(19) United States
(12) Patent Application Publication
(10) Pub. No.: US 2025/0022998 A1
(43) Pub. Date: Jan. 16, 2025

(54) FILM PACKAGE

(71) Applicant: Samsung Electronics Co., Ltd., Suwon-si (KR)

(72) Inventors: Seunghyun Cho, Suwon-si (KR); Jaemin Jung, Suwon-si (KR); Jeongkyu Ha, Suwon-si (KR)

(21) Appl. No.: 18/583,947

(22) Filed: Feb. 22, 2024

(30) Foreign Application Priority Data
Jul. 10, 2023 (KR) 10-2023-0088794

(51) Int. Cl. H01L 33/62; H01L 25/075; H01L 25/16; H01L 33/48

(52) U.S. Cl. CPC H01L 33/62; H01L 25/0753; H01L 25/167; H01L 33/486

(57) ABSTRACT

A film package includes a film substrate, vias penetrating through the film substrate, interconnection patterns on the film substrate, and a semiconductor chip electrically connected to at least one of the interconnection patterns and to the vias, wherein the interconnection patterns include input patterns, first output patterns, and second output patterns, the film package includes input pads on a surface of the film substrate, and the input patterns extend from the input pads, the film package includes first output pads positioned toward a first edge of the film substrate on a first surface of the film substrate, and the first output patterns extend from the first output pads, and the film package includes second output pads positioned toward a second edge of the film substrate on a second surface of the film substrate opposite to the first surface, and the second output patterns extend from the second output pads.

### CROSS-REFERENCE TO RELATED APPLICATION

This application claims benefit of priority to Korean Patent Application No. 10-2023-0088794 filed on Jul. 10, 2023 in the Korean Intellectual Property Office, the disclosure of which is incorporated herein by reference in its entirety.

### BACKGROUND

The present inventive concept relates to a film package.

Recently, in order to respond to the trend for miniaturization, thinning, and lightweightedness of electronic products, a chip on-film (COF) package technology using a flexible film substrate has been proposed. In the COF package technology, a semiconductor chip may be mounted on a film substrate using a flip chip bonding method and may be connected to an external device through an interconnection line. Such a COF package may be applied to portable terminal devices, such as cellular phones or personal digital assistants (PDAs), laptop computers, or panels of display devices.

### SUMMARY

An aspect of the present inventive concept is to provide a film package capable of effectively increasing an effective width.

According to an aspect of the present inventive concept, a film package includes a film substrate; vias penetrating through the film substrate; interconnection patterns on the film substrate; and a semiconductor chip electrically connected to at least one of the interconnection patterns and electrically connected to the vias, wherein the interconnection patterns include input patterns, first output patterns, and second output patterns, the film package includes input pads on a surface of the film substrate, and the input patterns extend from the input pads, the film package includes first output pads positioned toward a first edge of the film substrate on a first surface of the film substrate, and the first output patterns extend from the first output pads, and the film package includes second output pads positioned toward a second edge of the film substrate on a second surface of the film substrate opposite to the first surface, and the second output patterns extend from the second output pads.

According to another aspect of the present inventive concept, a film package includes a foldable film substrate; interconnection patterns on the film substrate; and a semiconductor chip electrically connected to at least one of the interconnection patterns, wherein the interconnection patterns include first output patterns extending from first output pads and second output patterns extending from second output pads, an arrangement of the first output pads forms a line, and, in an unfolded state of the film substrate, an arrangement of the second output pads forms an oblique line with respect to the arrangement of the first output pads.

According to another aspect of the present inventive concept, a film package includes a film substrate; interconnection patterns on the film substrate; a semiconductor chip electrically connected to at least one of the interconnection patterns; a first protective layer covering a portion of the interconnection patterns on a first surface of the film substrate; and a second protective layer covering another portion of the interconnection patterns on a second surface of the film substrate opposite to the first surface, wherein the film substrate includes a body on which at least a portion of the first protective layer is disposed and foldable portions extending from the body, at least a portion of the second protective layer being disposed on the foldable portions, in an unfolded state of the film substrate, one edge of each of the foldable portions forms an oblique line with respect to edges of the body, and the film substrate is additionally bendable in a folded state of the foldable portions.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a perspective view and a side view illustrating a structure in which first output pads of a film package are electrically connected to a display panel according to an example embodiment;

FIG. 2 is a perspective view and a side view illustrating a structure in which input pads of a film package are electrically connected to a driving printed circuit board (PCB) according to an example embodiment;

FIG. 3 is a perspective view and a side view illustrating a structure in which foldable portions of a film package are folded according to an example embodiment;

FIG. 4 is a perspective view and a side view illustrating a structure in which first and second output pads of a film package are electrically connected to a display panel according to an example embodiment;

FIG. 5 is a side view illustrating a structure in which foldable portions of a film package are additionally bendable in a folded state according to an example embodiment;

FIG. 6 is a plan view illustrating a surface of a film package according to an example embodiment;

FIG. 7 is a plan view illustrating a surface of a film package according to an example embodiment;

FIGS. 8 to 11 are plan views illustrating various structures in which first and second output pads of a film package are electrically connected to a display panel according to an example embodiment;

FIG. 12 is a plan view illustrating a structure in which a heat dissipation structure is added to a film package according to an example embodiment;

FIGS. 13 and 14 are side views illustrating a structure in which a heat dissipation structure is added to a film package according to an example embodiment;

FIGS. 15 and 16 are side views illustrating a multi-layer structure of a film substrate of a film package according to an example embodiment;

FIG. 17 is a side view illustrating a structure in which an adhesive layer is added to a second protective layer of a film package according to an example embodiment;

FIG. 18 is a side view illustrating a structure in which a second protective layer of a film package has a step according to an example embodiment;

FIG. 19 is a perspective view and a side view illustrating a structure in which an additional semiconductor chip is further disposed in a film package according to an example embodiment; and

FIG. 20 is a perspective view illustrating a film package electrically connecting a display panel to a driving PCB according to an example embodiment.

### DETAILED DESCRIPTION

In the following detailed description, reference is made to the accompanying drawings that show, by way of illustration, particular example embodiments in which the invention may be practiced. These example embodiments are described in sufficient detail to enable those skilled in the art to practice the invention. It is to be understood that the various example embodiments of the invention, although different, are not necessarily mutually exclusive. For example, a certain feature, structure, or characteristic described herein in connection with an example embodiment may be implemented within other example embodiments without departing from the spirit and scope of the invention. In addition, it is to be understood that the location or arrangement of individual elements within each disclosed example embodiment may be modified without departing from the spirit and scope of the invention. The following detailed description is, therefore, not to be taken in a limiting sense, and the scope of the present inventive concept is defined only by the appended claims, appropriately interpreted, along with the full range of equivalents to which the claims are entitled. In the drawings, like numerals refer to the same or similar functionality throughout the several views.

Hereinafter, example embodiments will be described in detail with reference to the accompanying drawings such that they may be easily practiced by those skilled in the art to which the present inventive concept pertains.

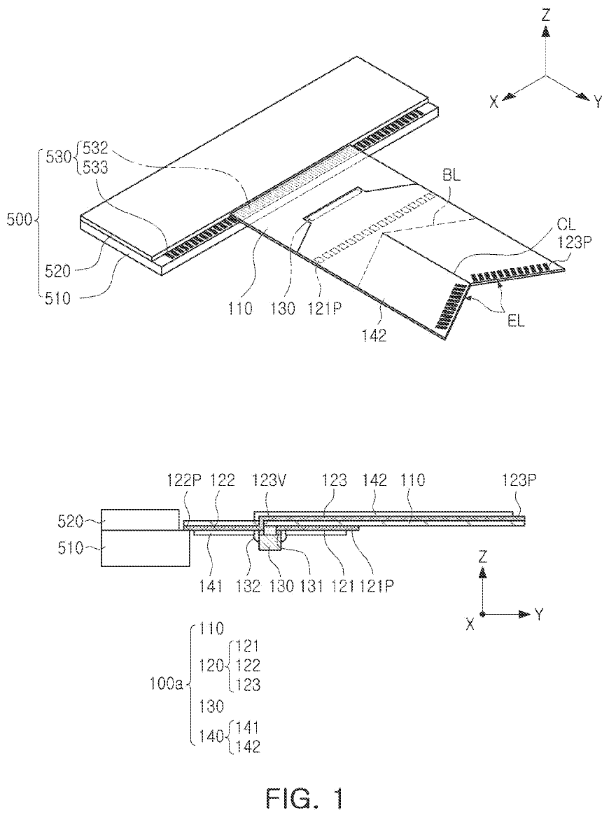

Referring to FIGS. 1, 6, and 7, film packages 100a and 100b according to an example embodiment may include a film substrate 110, interconnection patterns 120, and a semiconductor chip 130.

The film substrate 110 is a support substrate on which the semiconductor chip 130 is mounted, and may have one side (e.g., a first edge in a −Y-direction) and the other side (e.g., a second edge in a +Y-direction) opposing each other. The film substrate 110 may be formed of or include a material having ductility higher than that of an insulating material (e.g., prepreg) of a general printed circuit board (PCB). Accordingly, the film substrate 110 may be more easily bent than the general PCB, and may flexibly connect the display panel 500 to another structure (e.g., a driving PCB). For example, the film substrate 110 may be a flexible film formed of or including polyimide, which is a material having an excellent coefficient of thermal expansion and durability. The material of the film substrate 110 is not limited thereto, and for example, the film substrate 110 may be formed of a synthetic resin, such as epoxy resin, acrylic, polyether nitrile, polyether sulfone, polyethylene terephthalate, polyethylene naphthalate.

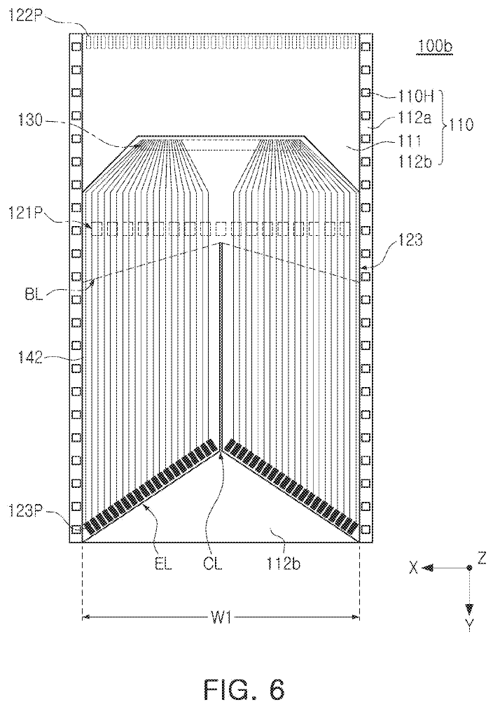

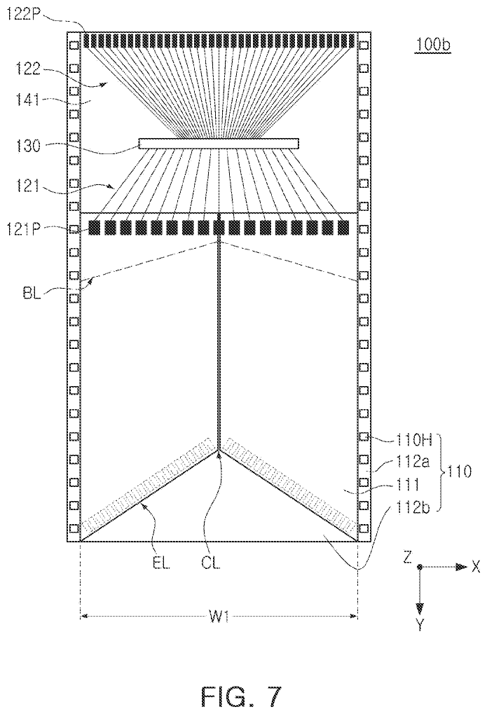

For example, the film substrate 110 may include a core region 111 and edge regions 112a and 112b (see, e.g., FIGS. 6 and 7), and the edge regions 112a and 112b may be selectively removed. For example, the edge regions 112a and 112b may be removed by cutting along boundary lines of the edge regions 112a and 112b. A portion of the edge regions 112a and 112b may have a structure in which the edge regions 112a and 112b of FIGS. 6 and 7 are removed from the film substrate 110 of FIG. 1. The edge region 112a may include sprocket holes 110H and may be used to control reeling and releasing of the film substrate 110. The core region 111 may be a perforation (PF) region.

The interconnection patterns 120 may be disposed on the film substrate 110. The interconnection patterns 120 may be formed of, for example, aluminum foil or copper foil. For example, the interconnection patterns 120 may be formed by patterning a metal film formed on the film substrate 110 through a process, such as casting, laminating, or electroplating. According to an example embodiment, the interconnection patterns 120 may include patterns respectively formed on one surface (e.g., a first surface in a −Z-direction) and the other surface (e.g., a second surface in a +Z-direction surface) of the film substrate 110 and vias 123V interconnecting the patterns through the film substrate 110.

The vias 123V may penetrate through the film substrate 110. Here, penetrating through the film substrate 110 includes a case in which a through position of an upper layer of the film substrate 110 and a lower layer thereof do not overlap each other when the film substrate 110 includes multiple layers. For example, each of the vias 123V may be implemented by forming holes in the film substrate 110 and then filling the holes with a conductive material (e.g., copper or aluminum) or may be implemented as a hollow structure by performing plating on side surfaces of the holes.

The semiconductor chip 130 may be electrically connected to at least one of the interconnection patterns 120 and electrically connected to the vias 123V. For example, the semiconductor chip 130 may be mounted on the film substrate 110 using a flip-chip bonding method. That is, the semiconductor chip 130 may be physically and electrically connected to the interconnection pattern 120 through connection bumps 131 (e.g., solder balls). An underfill resin 132 may be formed between the semiconductor chip 130 and the film substrate 110 to surround and seal the connection bumps 131. The underfill resin 132 may be formed using, for example, an insulating resin, such as epoxy resin. The underfill resin 132 may be formed to surround the connection bumps 131 within openings of a protective layer 140 described later.

The semiconductor chip 130 may be a display driving chip (DDI) used to drive a display. That is, the semiconductor chip 130 may be at least a portion of a display driving circuit. For example, the semiconductor chip 130 may include at least one source driving circuit generating an image signal using a data signal transmitted from a timing controller and outputting the image signal to a display panel 500 and at least one gate driving circuit outputting a scan signal including an ON/OFF signal of a transistor to the display panel 500. According to example embodiments, the semiconductor chip 130 may be one of a plurality of semiconductor chips each including a source driving circuit and a gate driving circuit. The semiconductor chip 130 may be, for example, a semiconductor die formed from and separated from a semiconductor wafer, to include an integrated circuit formed therein or thereon.

The ratio (aspect ratio) of a length of the semiconductor chip 130 in the first direction (e.g., an X-direction) to a length thereof in the second direction (e.g., a Y-direction) may be higher than that of a general semiconductor chip. For example, the aspect ratio of the semiconductor chip 130 may exceed 2. Therefore, even if the film substrate 110 is bent, the semiconductor chip 130 may be stably disposed on the film substrate 110.

The interconnection patterns 120 may include input patterns (e.g., wire lines) 121, first output patterns 122, and second output patterns 123. The density of the first output patterns 122 and the second output patterns 123 may be higher than that of the input patterns 121, and may be higher with increasing display resolution of the display panel 500. For example, a line width of each of the input patterns 121 may be wider than a line width of each of the first output patterns 122 and the second output patterns 123, and an interval between adjacent input patterns 121 may be greater than an interval between adjacent first output patterns 122 and may be greater than an interval between adjacent second output patterns 123. Similarly, the sum of a total number of first output pads 122P and a total number of second output pads 123P may be greater than the number of input pads 121P, and an area of each of the first output pads 122P and the second output pads 123P may be less than that of each of the input pads 121P.

For example, an average interval between the input patterns 121 may be greater than or equal to 50 μm and less than or equal to 500 μm, the total number of the input patterns 121 may be about 200, and the line width of each of the input patterns 121 may be about 10 μm. For example, an average interval between the first and second output patterns 122 and 123 may be greater than or equal to 15 μm and less than 50 μm, and the total number of first and second output patterns 122 and 123 may be greater than or equal to 900 or less than or equal to 2500, and the line width of each of the first and second output patterns 122 and 123 may be about 10 μm. For example, an average interval between the input pads 121P may be greater than or equal to 50 μm and less than or equal to 500 μm, the total number of input pads 121P may be about 200, and the size of each of the input pads 121P may be (15 to 25 μm)×(30 to 50 μm)×(˜15 μm). For example, an average interval (e.g., 20 μm) between the first and second output pads 122P and 123P may be greater than or equal to 15 μm and less than 50 μm, the total number of the first and second output pads 122P and 123P may be greater than or equal to 900 and equal to or less than 2500, and the size of each of the first and second output pads 122P and 123P may be (15 to 25 μm)×(30 to 50 μm)×(˜15 μm).

The first and second output patterns 122 and 123 may be connected to the semiconductor chip 130 through some of the connection bumps 131 offset to one side (e.g., toward a first edge in the −Y-direction, to be closer to the first edge than an opposite second edge in the −Y direction) and the input patterns 121 may be connected to the semiconductor chip 130 through the other of the connection bumps 131 more offset to the other side (e.g., toward a second edge in the +Y direction, to be closer to the second edge than the first edge in the −Y direction), but are not limited thereto. For example, the other of the connection bumps 131 more offset to the other side (e.g., toward the second edge in the +Y-direction) may be connected to some of the first and second output patterns 122 and 123 and the input patterns 121.

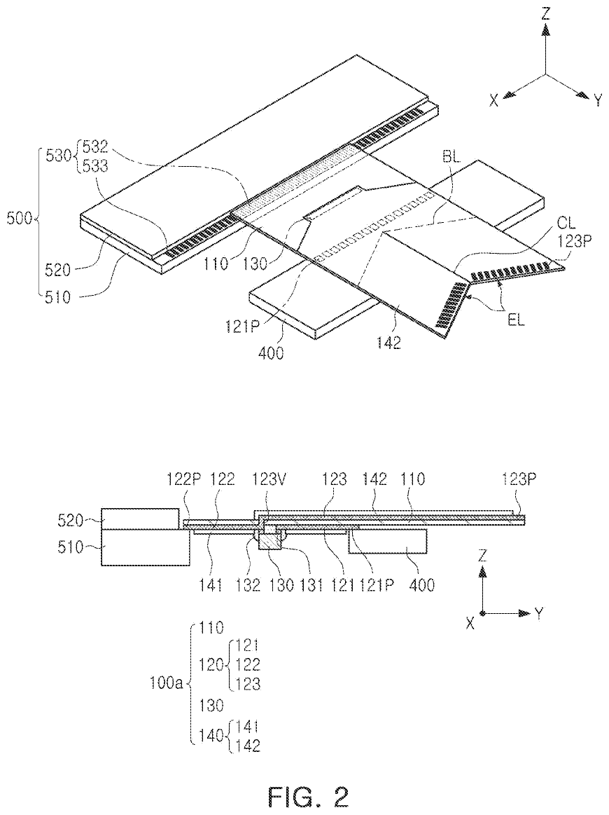

The input patterns 121 may include input pads 121P disposed to be offset to the other side (e.g., toward the second edge in the +Y-direction) on one surface (e.g., the −Z-direction surface) of the film substrate 110, and may extend from the input pads 121P to one side (e.g., toward the first edge in the −Y-direction). Referring to FIG. 2, the input patterns 121 may be electrically connected to a driving PCB 400 through the input pads 121P.

The film substrate 110 may include first output pads 122P disposed to be offset to one side (e.g., toward the first edge in the −Y-direction) on one surface (e.g., the −Z-direction surface) of the film substrate 110 and may extend from the first output pads 122P to the other side (e.g., toward the second edge in the +Y-direction). However, the invention is not limited thereto, and the first output pads 122P may be integrated with the first output patterns 122. The first output patterns 122 may extend away from the first output pads 122P. Here, in the inclined arrangement, the criterion of whether being inclined may be the center, and thus, the first output pads 122P may be arranged in a position away from the center of one surface (e.g., the −Z-direction surface) of the film substrate 110 to one side (e.g., toward the first edge in the −Y direction). For example, the first output pads 122P may be positioned between the first edge (the edge in the −Y direction) and the center of the film substrate 110. For example, the first output pads 122P may be positioned at the first edge (the edge in the −Y direction) of the film substrate 110. The first output pads 122P of the first output patterns 122 may contact and be connected to the first panel pads 532 of the panel connection interconnection 530 of the display panel 500. Accordingly, the first output patterns 122 may be electrically connected to the display panel 500. Depending on the design, in a state in which the first output pads 122P and the first panel pads 532 are in contact with and connected to each other, an insulating adhesive material, such as an adhesive polymer, an epoxy-based polymer, an acrylic-based polymer, or a silicon-containing material, may be applied to adhere the first output pads 122P and the first panel pads 532 to each other and may be cured by ultraviolet rays after being applied.

Since a width W1 of the arrangement of the first output pads 122P may be determined by the width of the film substrate 110 (see, e.g., FIGS. 6 and 7), the width W1 may increase as the width of the film substrate 110 is increased. However, as the width of the film substrate 110 increases, the difficulty of securing reliability (and/or manufacturing efficiency) of the film substrate 110 may increase. For example, the width of the film substrate 110 may be selected from among standardized widths (e.g., 35 mm, 48 mm, and 70 mm), and the standardized widths may be determined based on a manufacturing process of the film substrate 110. If the standardized widths are to be changed, a customizing element may be added to the process of manufacturing the film substrate 110. This may increase the difficulty of securing reliability (and/or manufacturing efficiency) of the film substrate 110.

The second output patterns 123 may include second output pads 123P disposed to be offset to the other side (e.g., toward the second edge in the +Y-direction) on the other surface (e.g., the +Z-direction surface) of the film substrate 110 and may extend to one side (e.g., toward the first edge in the −Y-direction) from the second output pads 123P. Here, in the inclined arrangement, the criterion of whether being inclined may be the center, and thus, the second output pads 123P may be arranged in a position moved from the center of the other surface (e.g., the +Z-direction surface) of the film substrate 110 to the other side (e.g., +Y direction). For example, the distance from the second output pad 123P to the second edge in the +Y direction may decrease with increasing distance from the center of the film substrate 110 in a width direction as shown, e.g., in FIG. 6.

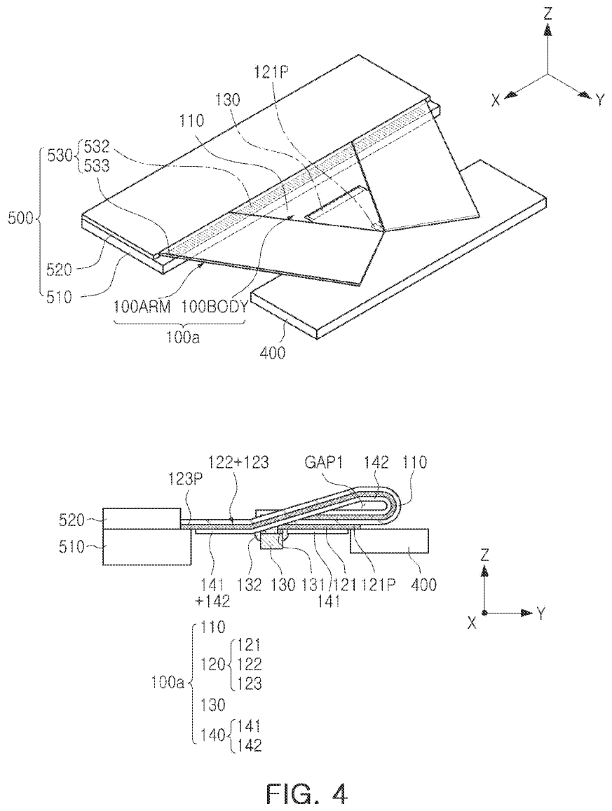

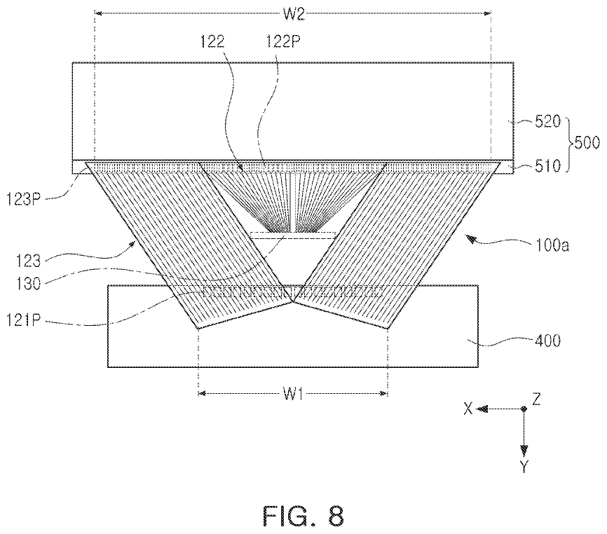

Referring to FIGS. 1 to 3, since the film substrate 110 may be flexibly bent, it may be folded along fold lines BL. Accordingly, referring to FIGS. 4 and 8, in the second output patterns 123, the second output pads 123P may contact and be connected to the second panel pads 533 of the panel connection interconnection 530 of the display panel 500. Accordingly, the second output patterns 123 may be electrically connected to the display panel 500.

The total width (W2 of FIG. 8) of the arrangement of the first output pads 122P and the arrangement of the second output pads 123P may be twice or more of the width W1 of the arrangement of the first output pads 122P and may be twice or more of the width of the film substrate 110. Accordingly, the film packages 100a and 100b according to an example embodiment may be more widely connected to the display panel 500 even without changing the width of the film substrate 110. That is, an effective width of the film packages 100a and 100b may be widened.

In addition, since the effective width of the film packages 100a and 100b may be widened, a fan-out structure (e.g., a panel connection interconnection in a bezel) in which the panel connection interconnection 530 is laterally spread to be extended may be omitted in the display panel 500, and thus, an image region 520 of the display panel 500 may be effectively widened. That is, the ratio of the upper surface area of the image region 520 to the upper surface area of a transparent substrate 510 of the display panel 500 may be higher. As the ratio is higher, the degree of freedom of arrangement of the display panel 500 in the electronic device may increase and the degree of freedom of design of the electronic device may also increase.

Referring to FIGS. 1, 6, and 7, the arrangement of the first output pads 122P may form a line, and in an unfolded state of the film substrate 110, the arrangement of the second output pads 123P may form an oblique line with respect to the arrangement of the first output pads 122P. The term “oblique” may be defined as forming an angle that is neither parallel nor perpendicular.

Since the fold lines BL of the film substrate 110 may be oblique with respect to one side and the other side direction (e.g., the Y-direction) of the film substrate 110, the position of the second output pads 123P may move not only in the Y-direction but also in the X-direction when the film substrate 110 is folded. Accordingly, the second output pads 123P may move to a position extending from the end of the line of the first output pads 122P when contacting and connected to the second panel pads 533, and the arrangement of the second output pads 123P may be parallel to the arrangement of the first output pads 122P in the folded and connected state (see, e.g., FIG. 4). Accordingly, the film packages 100a and 100b according to an example embodiment may be more widely connected to the display panel 500 even without changing the width of the film substrate 110. That is, the effective width of the film packages 100a and 100b may be effectively widened.

In the unfolded state of the film substrate 110, the arrangement of the second output pads 123P may form an oblique line with respect to the extending direction (e.g., the Y-direction) of the second output patterns 123. After the film substrate 110 is folded, the extending direction (e.g., the Y-direction) of the second output patterns 123 may be oblique to the arrangement of the first output pads 122P. That is, the second output patterns 123 may form a fan-out structure according to the folding of the film substrate 110.

In the unfolded state of the film substrate 110, a boundary line EL on the other side (e.g., the second edge) of the film substrate 110 may include an oblique line with respect to the boundary line on one side (e.g., the first edge) of the film substrate 110. Therefore, after the film substrate 110 is folded, the film substrate 110 may be prevented from covering a portion of the image region 520 of the display panel 500. For example, the boundary line EL on the other side (e.g., the +Y-direction) of the film substrate 110, in a state of being parallel to the boundary line on one side (e.g., the −Y-direction) of the film substrate, may be formed because the edge region (112b of FIGS. 6 and 7) of the film substrate 110 is removed.

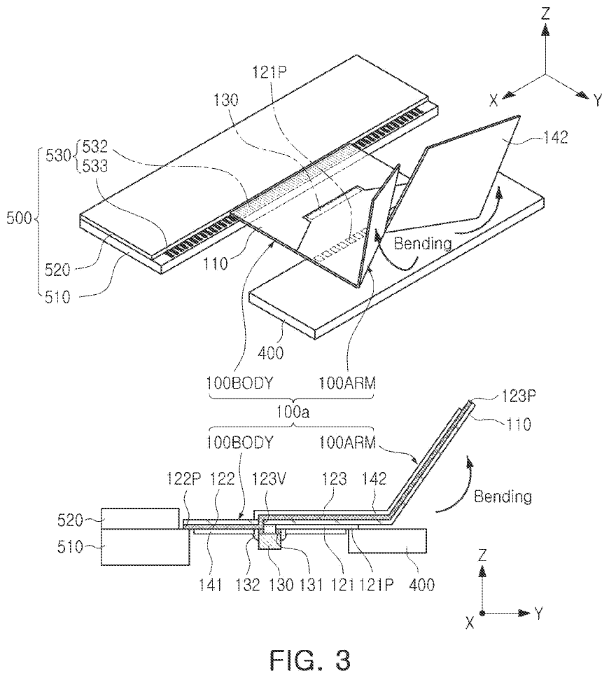

Referring to FIGS. 3 and 4, the film substrate 110 may include a body 100BODY in which first output pads 122P are disposed and foldable portions 100ARM, in which the second output pads 123P are arranged, extending from each body 100BODY.

One end of each of the foldable portions 100ARM may be connected to the body 100BODY, and a position of the other end of each of the foldable portions 100ARM may freely move by flexible folding of the foldable portions 100ARM. The foldable portions 100ARM may be separated from each other along the cutting line CL of the film substrate 110.

In the unfolded state of the film substrate 110, the arrangement of the second output pads 123P disposed in each of the foldable portions 100ARM may be oblique to the direction (e.g., the +Y-direction) in which the foldable portions 100ARM extend from the body 100BODY and may be oblique to the extending direction (e.g., the +Y-direction) of the second output patterns 123 respectively arranged in the foldable portions 100ARM.

The arrangement of the first output pads 122P forms a line, and the foldable portions 100ARM may be foldable so that the second output pads 123P are continuously arranged to extend away from both ends of the arrangement of the first output pads 122P.

According to the design, in a state in which the second output pads 123P and the second panel pads 533 are in contact with and connected to each other, an insulating adhesive material, such as an adhesive polymer, an epoxy-based polymer, an acrylic-based polymer, or a silicon-containing material, may be applied to adhere the second output pads 123P and the second panel pads 533 to each other, and may be cured by ultraviolet rays after being applied.

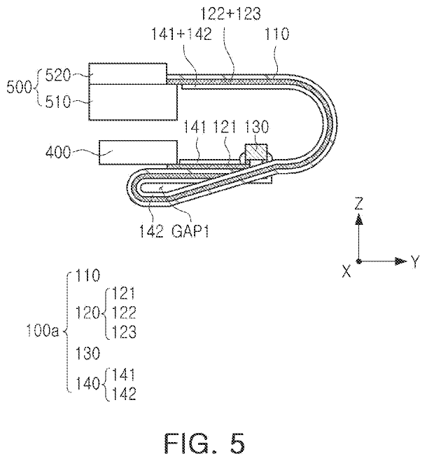

Referring to FIG. 5, the film substrate 110 may be additionally bendable in a folded state of the foldable portions 100ARM. Folding of the foldable portions 100ARM may increase the effective width of the film packages 100a and 100b, and additional bending of the film substrate 110 may flexibly connect the display panel 500 to the driving PCB 400. Since folding of the foldable portions 100ARM may not adhere one portion of each of the foldable portions 100ARM to another portion, an empty space GAP1 may be formed between one portion of each of the foldable portions 100ARM and another portion.

The protective layer 140 may be disposed on the film substrate 110 to cover at least a portion of the interconnection patterns 120 to protect the interconnection patterns 120 from external physical and/or chemical damage. The protective layer 140 may be formed of an insulating material, for example, solder resist or dry film resist. Since the solder resist or dry film resist may be a material, different from polyimide of the film substrate 110, the film substrate 110 and the protective layer 140 may include different materials.

The protective layer 140 may have openings penetrating through the protective layer 140, and the openings may be formed by a patterning method (e.g., a photo-lithography method). Some of the openings may be passages connecting the interconnection patterns 120 to the semiconductor chip 130, and the other of the openings may be input passages exposing the input pads 121P, the first output pads 122P, and the second output pads 123P.

The protective layer 140 may include a first protective layer 141 and a second protective layer 142. The first protective layer 141 may cover the first output patterns 122 and expose the first output pads 122P on one surface (e.g., the −Z-direction surface) of the film substrate 110, and the second protective layer 142 may cover the second output pads 123P and expose the second output pads 123P on the other surface (e.g., the +Z-direction surface) of the film substrate 110.

For example, the first protective layer 141 may not be disposed on the foldable portions 100ARM, and a coverage range of the first protective layer 141 and a coverage range of the second protective layer 142 may overlap in a portion (e.g., a portion including the center of the film substrate 110) of the body 100BODY and may not overlap in another portion (e.g., a portion on one side of the film substrate 110) of the body 100BODY. Accordingly, since the thickness of the foldable portions 100ARM may decrease, the foldable portions 100ARM may be folded more freely. Also, the total thickness of the foldable portions 100ARM, after the foldable portions 100ARM are folded, may be prevented from becoming too large. In addition, since the protective layer 140 may be disposed to be concentrated on a region having a relatively high level of protection importance among the regions on both sides of the film substrate 110, the interconnection patterns 120 may be more efficiently protected.

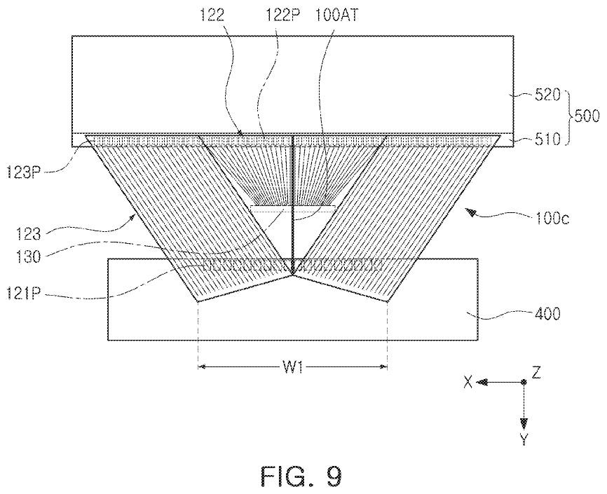

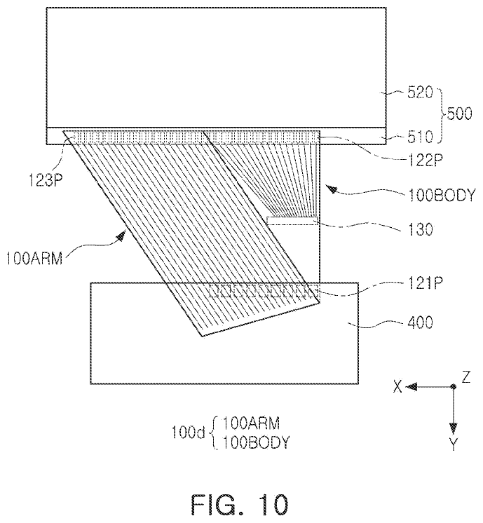

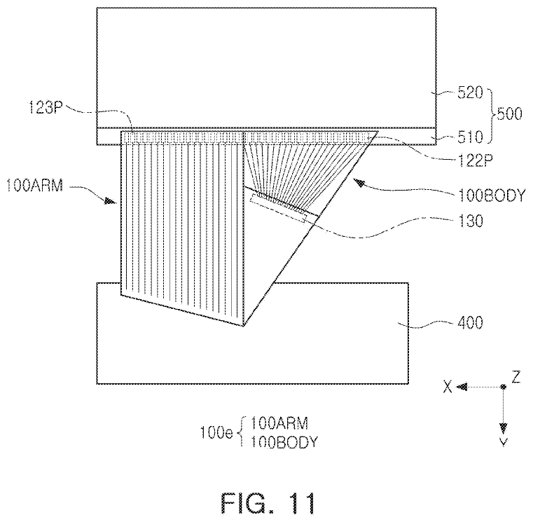

Referring to FIGS. 8 to 11, film packages 100a, 100c, 100d, and 100e according to an example embodiment may be implemented in one of various forms according to design. Referring to FIG. 9, the film package 100c may have a structure in which a first portion (e.g., a +X-direction) and a second portion (e.g., a −X-direction) of the film package 100a of FIG. 8, are separately manufactured and adhered to each other by an adhesive member 100AT. Referring to FIG. 10, the film package 100d may have a structure including a single foldable portion 100ARM. Referring to FIG. 11, the film package 100e may have a structure in which the body 100BODY, rather than the foldable portion 100ARM, is oblique with respect to the first output pads 122P, and the semiconductor chip 130 may be oblique with respect to the arrangement of the first output pads 122P.

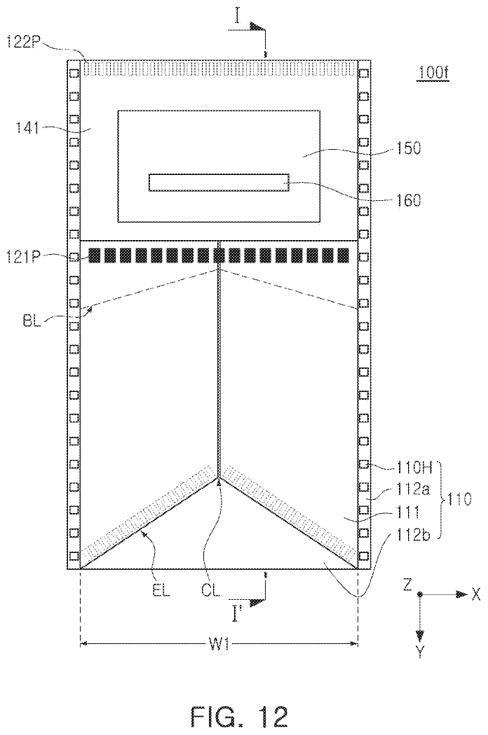

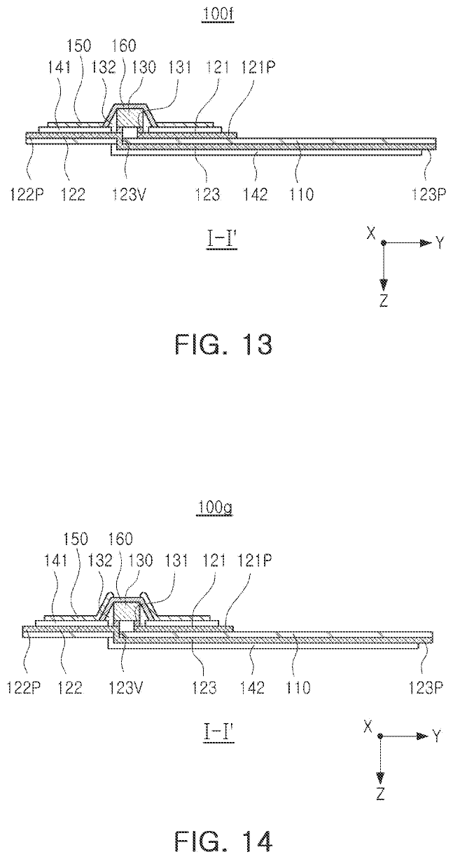

Referring to FIGS. 12 to 14, the film packages 100f and 100g according to an example embodiment may further include a heat dissipation structure, and the heat dissipation structure may include a thermally conductive film 150 and/or a thermally conductive resin 160. I-I′ in FIGS. 13 and 14 represents a cross section from I to I′ in FIG. 12.

The thermally conductive film 150 may have a relatively high thermal conductivity, for example, about 200 W/mK or more. The thermally conductive film 150 may be formed of or include a metal, such as aluminum and/or copper, or may include a carbon-containing material, such as graphene, carbon nanotubes, and/or graphite. Upper and lower surfaces of the thermally conductive film 150 may be covered with an insulating adhesive film (not shown) formed of or including an epoxy-based polymer, an acrylic-based polymer, or a silicon-containing material. According to an example embodiment, a protective film (not shown) may be formed on one surface of the insulating adhesive film (not shown) facing the opposite side of the film substrate 110. The protective film (not shown) may prevent the thermally conductive film 150 from being damaged (e.g., oxidized or corroded) by external impurities. The protective film (not shown) may be formed of or include, for example, at least one of insulating polymers, such as polyimide, polyethylene terephthalate (PET), and polyethylene naphthalate (PEN).

The thermally conductive film 150 may be disposed on the protective layer 140 to cover the thermally conductive resin 160. In the present inventive concept, the thermally conductive film 150 covering the periphery of the semiconductor chip 130 is introduced, and by forming a first through-hole vertically overlapping the upper surface of the semiconductor chip 130 in the thermally conductive film 150, heat dissipation characteristics and process efficiency of the film packages 100f and 100g may be improved. The upper surface of the semiconductor chip 130 may be entirely covered with the thermally conductive resin 160. The thermally conductive resin 160 may be a resin for heat dissipation and may be a transparent resin.

For example, the thermally conductive resin 160 may be a resin having a thermal conductivity of about 4 W/mK or more, and may include a transparent resin and a heat dissipating filler dispersed in the transparent resin. Transparent resins may include, for example, at least one of an epoxy resin, an acrylic resin, a polyamide-based resin, an urethane-based resin, an urea-based resin, a melamine-based resin, a polyester-based resin, a phenoxy resin, a phenol-based resin, a silicone-based resin, a polyethylene resin, a polypropylene resin, a polystyrene resin, a polyvinyl chloride resin, a chlorinated polyethylene resin, a polychlorinated butyral resin, and an ethylene vinyl acetate resin. Heat-dissipating fillers may include, for example, at least one of silicon carbide, magnesium oxide, titanium dioxide, aluminum nitride, silicon nitride, boron nitride, aluminum oxide, silica, zinc oxide, barium titanate, strontium titanate, beryllium oxide, manganese oxide, zirconia oxide, and boron oxide. The thermally conductive resin 160 and the underfill resin 132 are separated by an interface and may include different materials.

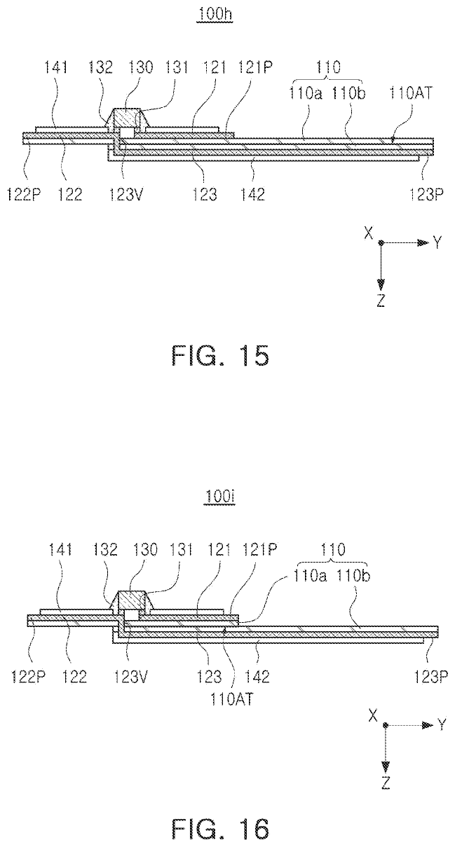

Referring to FIGS. 15 and 16, the film substrate 110 of the film packages 100h and 100i according to an example embodiment may include multiple layers 110a and 110b according to design. An adhesive layer 110AT may adhere the multiple layers 110a and 110b to each other. For example, the upper and lower portions of the film packages 100h and 100i may be separately manufactured and then adhered to each other by the adhesive layer 110AT. Depending on the design, the adhesive layer 110AT may be omitted when the multiple layers 110a and 110b are manufactured together.

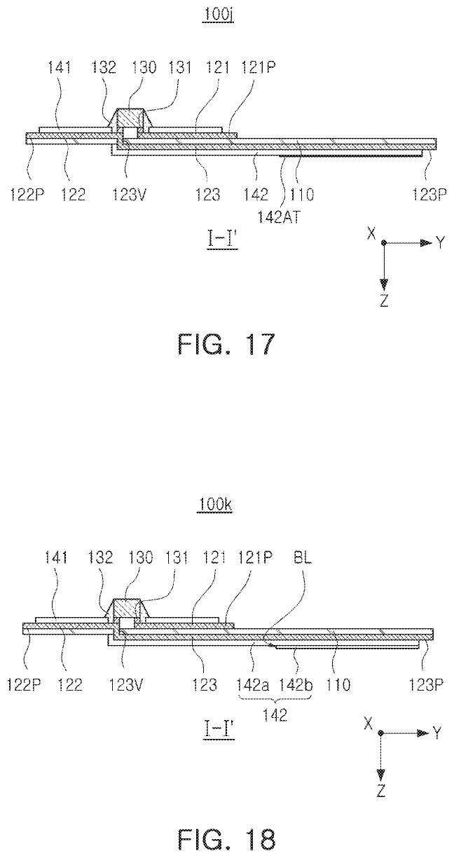

Referring to FIG. 17, a film package 100j according to an example embodiment may further include an adhesive layer 142AT disposed on a surface opposite to the surface facing the film substrate 110 on the second protective layer 142. As the film substrate 110 is folded, the adhesive layer 142AT may contact a portion of the film substrate 110 and adhere the portion of the film substrate 110 to the second protective layer 142. Accordingly, durability of the film package 100j after the film substrate 110 is folded may be further improved. For example, the adhesive layer 142AT, the adhesive member 100AT of FIG. 8, and the adhesive layer 110AT of FIGS. 15 and 16 may each be formed of or include an insulating adhesive material, such as an adhesive polymer, an epoxy-based polymer, an acrylic-based polymer, or silicon-containing material, and may be cured by ultraviolet light during adhesion.

Referring to FIG. 18, a film package 100k according to an example embodiment may further include a step formed on a surface opposite to the surface facing the film substrate 110 in the second protective layer 142. Accordingly, the film substrate 110 may be more stably folded along the fold lines BL, and the durability of the film package 100k may be further improved. For example, the step may be formed along the fold lines BL of the film substrate 110, and may be formed by a difference between areas of double layers 142a and 142b of the second protective layer 142 in the horizontal direction. Since the shape of the step may be angular, the step may be implemented as a groove or recess formed in an angular shape on the surface opposite to the surface facing the film substrate 110 in the second protective layer 142. Since the step may not be formed on the first protective layer 141, the step of the second protective layer 142 may be more angular than each point on the surface opposite to the surface facing the film substrate 110 in the first protective layer 141.

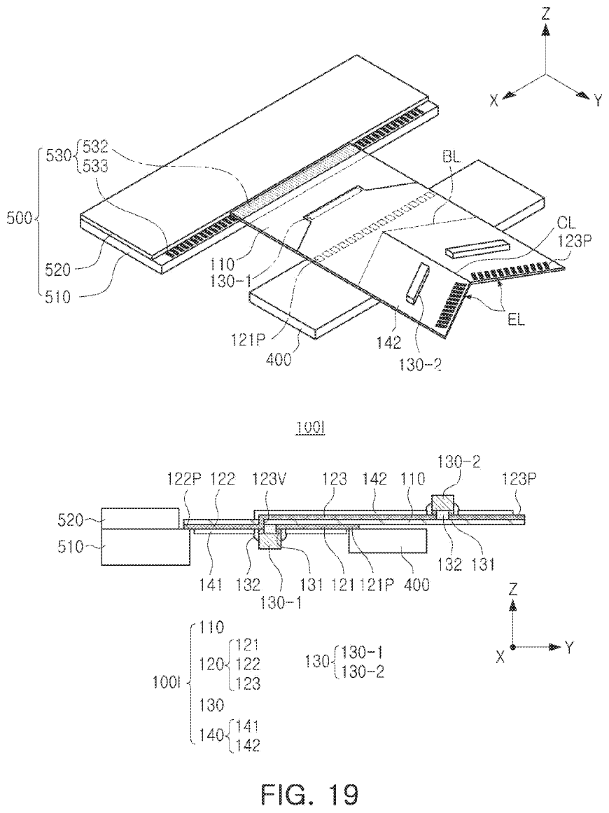

Referring to FIG. 19, a film package 1001 according to an example embodiment may further include an additional semiconductor chip 130-2 disposed on the other surface (e.g., the +Z-direction surface) of the film substrate 110. A combination of the semiconductor chip 130-1 and the additional semiconductor chip 130-2 may be a display driving circuit. For example, one of the semiconductor chip 130-1 and the additional semiconductor chip 130-2 may be a source driving circuit generating an image signal using a data signal transmitted from a timing controller and outputting the image signal to the display panel 500, and the other of the semiconductor chip 130-1 and the additional semiconductor chip 130-2 may be a gate driving circuit outputting a scan signal including an ON/OFF signal of a transistor to the display panel 500.

The combination of the semiconductor chip 130-1 and the additional semiconductor chip 130-2 may be electrically connected to the input patterns 121, the first output patterns 122, and the second output patterns 123. If the combination of the semiconductor chip 130-1 and the additional semiconductor chip 130-2 is integrated into a single semiconductor chip, the semiconductor chip 130 may be electrically connected to the input patterns 121, the first output patterns 122, and the second output patterns 123.

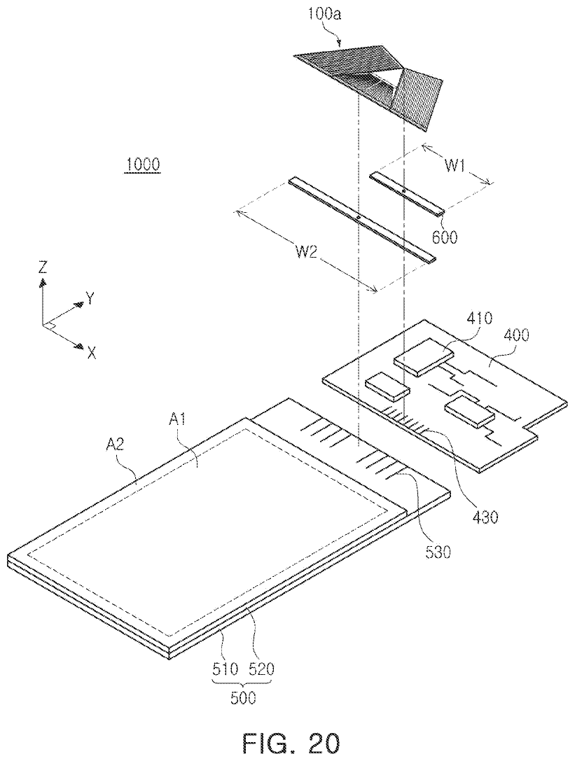

Referring to FIG. 20, a film package 100a according to an example embodiment may be connected to the driving PCB 400 and the display panel 500. The interconnection patterns of the film package 100a may be electrically connected to the driving connection interconnection 430 of the driving PCB 400 and the panel connection interconnection 530 of the display panel 500, respectively. The film package 100a may receive a signal output from the driving PCB 400 and transmit the signal to the display panel 500.

In an example embodiment, the package module 1000 may include at least one film package 100a. For example, when the display panel 500 is intended to provide a small screen, such as mobile phones, or support a relatively low resolution, the driving PCB 400 and the display panel 500 may be connected to each other through a single film package. In this case, the film package 100a may be connected to one side of the display panel 500. For example, when the display panel 500 is intended to provide a large screen, such as televisions, or support a relatively high resolution, the number of film packages flexibly connecting the driving PCB 400 and the display panel may be plural.

Since the film package 100a according to an example embodiment may effectively widen the effective width W2, the number of required film packages 100a compared to the size and resolution of the display panel 500 may be reduced.

Each of the input pattern 121 and the output pattern 122 of the film package 100a may be connected to each of the driving connection interconnection 430 of the driving PCB 400 and the panel connection interconnection 530 of the display panel 500 by the anisotropic conductive layer 600. The anisotropic conductive layer 600 may be an anisotropic conductive film or an anisotropic conductive paste in which conductive particles are dispersed in an insulating adhesive layer. The anisotropic conductive layer 600 may be interposed between facing electrodes and may have anisotropic electrical properties of being electrically conducted only in the direction in which the electrodes face each other (a Z-axis direction) and insulated in the direction between the neighboring electrodes (an X-axis direction).

One or more driving circuit chips 410 capable of simultaneously or sequentially applying power and signals to the film package 100a may be mounted on the driving PCB 400.

The display panel 500 may be, for example, a liquid crystal display (LCD) panel, a light emitting diode (LED) panel, an organic LED (OLED) panel, a plasma display panel (PDP), or the like.

The display panel 500 may include a transparent substrate 510, an image region 520 formed on the transparent substrate 510, and a panel connection interconnection 530. The transparent substrate 510 may be, for example, a glass substrate or a transparent flexible substrate. The image region 520 may have a display region A1 displaying an image and a peripheral region A2 applying a driving signal to the display region A1. A plurality of pixels in the display region A1 may be connected to a plurality of corresponding panel connection interconnections 530 and operated according to signals provided by a semiconductor chip mounted on the film package 100a.

Since the film package 100a according to an example embodiment may effectively widen the effective width W2, the display panel 500 may not have a structure in which the panel connection interconnection 530 is laterally spread to be extended. Accordingly, the display panel 500 may have a structure in which the image region 520 may be wider or the transparent substrate 510 may be further reduced and a bezel may be omitted.

A film package according to an example embodiment may effectively widen an effective width. For example, since the film package may be more widely connected to the display panel, the image region of the display panel may be more efficiently widened or the degree of freedom in design of the display panel may be increased. Furthermore, the degree of freedom of arrangement of the display panel in an electronic device in which the display panel may be disposed may be further increased, and the degree of freedom in design of the electronic device may be further increased.

While example embodiments have been illustrated and described above, it will be apparent to those skilled in the art that modifications and variations could be made without departing from the scope of the present inventive concept.

What is claimed is:

1. A film package comprising:
a film substrate;
vias penetrating through the film substrate;
interconnection patterns on the film substrate; and
a semiconductor chip electrically connected to at least one of the interconnection patterns and electrically connected to the vias,
wherein
the interconnection patterns include input patterns, first output patterns, and second output patterns,
the film package includes input pads on a surface of the film substrate, and the input patterns extend from the input pads,
the film package includes first output pads positioned toward a first edge of the film substrate on a first surface of the film substrate, and the first output patterns extend from the first output pads, and
the film package includes second output pads positioned toward a second edge of the film substrate on a second surface of the film substrate opposite to the first surface, and the second output patterns extend from the second output pads.

2. The film package of claim 1, wherein the film substrate includes:
a body in which the first output pads are disposed; and
foldable portions, in which the second output pads are disposed, each of the foldable portions extending from the body.

3. The film package of claim 2, wherein
an arrangement of the first output pads forms a line,
the foldable portions are foldable so that, in a folded state, the second output pads are arranged at opposite ends of the arrangement of the first output pads, and
the film substrate is additionally bendable in a folded state of the foldable portions.

4. The film package of claim 2, wherein
an arrangement of the first output pads forms a line, and,
in an unfolded state of the film substrate, an arrangement of the second output pads forms an oblique line with respect to the arrangement of the first output pads.

5. The film package of claim 4, wherein, in the unfolded state of the film substrate, a first edge of the film substrate includes an oblique line with respect to a second edge of the film substrate opposite to the first edge.

6. The film package of claim 2, wherein, in an unfolded state of the film substrate, an arrangement of the second output pads forms an oblique line with respect to an extending direction of the second output patterns.

7. The film package of claim 1, further comprising:
a first protective layer covering the first output patterns and exposing the first output pads on a first surface of the film substrate; and
a second protective layer covering the second output patterns and exposing the second output pads on a second surface of the film substrate.

8. The film package of claim 7, wherein a surface of the second protective layer opposite to the surface facing the film substrate has a step.

9. The film package of claim 7, further comprising:
connection bumps connecting the semiconductor chip to at least one of the interconnection patterns on a surface of the film substrate; and
an underfill resin surrounding the connection bumps.

10. The film package of claim 7, wherein the film substrate includes polyimide, different from a material of each of the first protective layer and the second protective layer.

11. The film package of claim 1, wherein
the semiconductor chip is at least portion of a display driving circuit and is disposed on a surface of the film substrate, and
the display driving circuit is electrically connected to the input patterns, the first output patterns, and the second output patterns.

12. The film package of claim 11, further comprising:
at least one additional semiconductor chip which is another portion of the display driving circuit,
wherein the at least one additional semiconductor chip is disposed on a surface of the film substrate opposite to the surface of the film substrate on which the semiconductor chip is disposed.

13. A film package comprising:
a foldable film substrate;
interconnection patterns on the film substrate; and
a semiconductor chip electrically connected to at least one of the interconnection patterns,
wherein the interconnection patterns include first output patterns extending from first output pads and second output patterns extending from second output pads,
an arrangement of the first output pads forms a line, and,
in an unfolded state of the film substrate, an arrangement of the second output pads forms an oblique line with respect to the arrangement of the first output pads.

14. The film package of claim 13, wherein
the first output pads are positioned toward a first edge on a first surface of the film substrate, and
the second output pads are positioned toward a second edge on a second surface of the film substrate, the first edge being opposite to the second edge and the first surface being opposite to the second surface.

15. The film package of claim 14, further comprising:
vias penetrating through the film substrate;
a first protective layer covering the first output patterns and exposing the first output pads on the first surface of the film substrate; and
a second protective layer covering the second output patterns and exposing the second output pads on the second surface of the film substrate.

16. The film package of claim 15, wherein
the interconnection patterns further include input patterns extending from input pads,
the semiconductor chip is at least a portion of a display driving circuit, and
the display driving circuit is electrically connected to the input patterns, the first output patterns, and the second output patterns.

17. The film package of claim 16, wherein
the film substrate includes:
a body in which the first output pads are disposed; and
foldable portions, in which the second output pads are disposed, each of the foldable portions extending from the body,
wherein, in an unfolded state of the film substrate, an arrangement of the second output pads respectively disposed on the foldable portions is oblique with respect to a direction in which the foldable portions extend from the body, and oblique with respect to an extending direction of the second output patterns respectively disposed in the foldable portions.

18. The film package of claim 17, wherein
the foldable portions are foldable so that in a folded state, the second output pads are arranged at opposite ends of the arrangement of the first output pads, and
the film substrate is additionally bendable in the folded state of the foldable portions.

19. A film package comprising:
a film substrate;
interconnection patterns on the film substrate;
a semiconductor chip electrically connected to at least one of the interconnection patterns;
a first protective layer covering a portion of the interconnection patterns on a first surface of the film substrate; and
a second protective layer covering another portion of the interconnection patterns on a second surface of the film substrate opposite to the first surface,
wherein the film substrate includes a body on which at least a portion of the first protective layer is disposed and foldable portions extending from the body, at least a portion of the second protective layer being disposed on the foldable portions,
in an unfolded state of the film substrate, one edge of each of the foldable portions forms an oblique line with respect to edges of the body, and
the film substrate is additionally bendable in a folded state of the foldable portions.

20. The film package of claim 19, wherein
the first protective layer is not disposed on the foldable portions, and
a coverage range of the first protective layer and a coverage range of the second protective layer overlap in a portion of the body and do not overlap in another portion of the body.
